(19) United States
(12) Patent Application Publication
(10) Pub. No.: US 2014/0039820 A1
(43) Pub. Date: Feb. 6, 2014

(54) QUANTITATIVE SERIES RESISTANCE IMAGING OF PHOTOVOLTAIC CELLS

(71) Applicants: Thorsten Trupke, New South Wales (AU); Juergen Weber, New South Wales (AU)

(72) Inventors: Thorsten Trupke, New South Wales (AU); Juergen Weber, New South Wales (AU)

(73) Assignee: BT IMAGING PTY LTD, Haymarket, New South Wales (AU)

(21) Appl. No.: 14/110,712

(22) PCT Filed: Apr. 17, 2012
(86) PCT No.: PCT/AU12/00389

§ 371 Date: Oct. 9, 2013

(30) Foreign Application Priority Data
Apr. 18, 2011 (AU) 2011901442

(51) Int. Cl. G01R 27/02; G01J 1/42

(52) U.S. Cl. CPC G01R 27/02; G01J 1/42
USPC 702/65

(57) ABSTRACT

Luminescence-based methods are disclosed for determining quantitative values for the series resistance across a photovoltaic cell, preferably without making electrical contact to the cell. Luminescence signals are generated by exposing the cell to uniform and patterned illumination with excitation light selected to generate luminescence from the cell, with the illumination patterns preferably produced using one or more filters selected to attenuate the excitation light and transmit the luminescence.

### FIELD OF THE INVENTION

The present invention relates to the characterisation of photovoltaic cells, and in particular to methods for quantitatively determining the spatial variation of series resistance across photovoltaic cells. However, it will be appreciated that the invention is not limited to this particular field of use.

### RELATED APPLICATIONS

The present application claims priority from Australian provisional patent application No 2011901442, the contents of which are incorporated herein by reference.

### BACKGROUND OF THE INVENTION

Any discussion of the prior art throughout this specification should in no way be considered as an admission that such prior art is widely known or forms part of the common general knowledge in the field.

Production of a photovoltaic (PV) cell typically begins with a bare wafer of a semiconductor material such as p-type (e.g. boron-doped) multicrystalline (mc) or monocrystalline silicon. During a typical production process an n-type emitter layer is formed on the front surface of the wafer, e.g. by phosphorus diffusion, followed by formation of a metal grid by screen printing or a plating process. The metal grid typically comprises multiple fingers connected to one or more bus bars. The remaining p-type part of the wafer (the ‘base’) is also contacted by metallisation of the entire rear surface, providing the other cell terminal. Various other metallisation patterns are also known; for example some cell designs have a metal grid on both the front and rear surfaces, while others have metal contacts on the rear surface only, or have point contacts on the rear surface instead of full area metallisation. In operation, above band-gap photons generate electron-hole pairs in the silicon, some of which are collected by the p-n junction creating majority carrier currents in the n- and p-type silicon layers. This current flows laterally along the emitter layer to the metal fingers, thence along the fingers and the bus bars to be extracted as current from the cell terminals. The same current flows through the base silicon layer and associated metal contacts.

Regions of a good quality PV cell are laterally connected in parallel via low series resistance. One common mode of PV cell failure or undesirably low efficiency is that regions become electrically isolated from each other or poorly connected, disrupting the carrier flow. For example metal fingers can break during manufacture, or be formed with small discontinuities, particularly during screen printing of designs with extremely thin fingers to maximise the exposed silicon surface area. Electrical current generated in the vicinity of broken fingers cannot be collected as effectively, resulting in a reduction of cell efficiency. Other failure modes that can disrupt current flow, and therefore increase the local series resistance, include high contact resistance between the metal fingers or the rear contact and the respective silicon surface, and cracks in the silicon.

Despite the fact that such failure modes are responsible for significant rejection rates of PV cells, they often cannot be identified by existing inspection techniques (e.g. machine vision optical inspection) with sufficient speed for inspecting every cell, or at least a significant fraction of the cells, coming off a production line that currently may operate at up to 1800 or even 3600 wafers per hour. Although machine vision can often detect broken fingers, it cannot discern areas with high contact resistance. Current-voltage (IV) testing, performed routinely by PV cell manufacturers on finished cells, can determine global series resistance and therefore identify defective cells, but gives no information as to the location or cause of high series resistance (i.e. defective) regions.

Several inspection techniques based on luminescence imaging have been proposed for identifying poorly connected or electrically isolated regions of silicon PV cells, with the luminescence generated either by optical excitation, electrical excitation or a combination thereof, e.g. optical excitation with simultaneous current injection or extraction. In general, ‘electrical excitation’ can include applying a voltage or load across the cell terminals, or injecting current into or extracting current from the cell terminals. For the purposes of this specification we will refer to an image of luminescence generated by application of a voltage as an electroluminescence (EL) image, and to an image of luminescence generated by application of optical excitation alone as a photoluminescence (PL) image. Descriptions of these ‘series resistance imaging’ techniques can be found for example in published PCT patent application Nos WO 07/128,060 A1, WO 09/129,575 A1 and WO 11/023,312 A1, published US application No US 2011/0012636 A1, J. Haunschild et al. Phys. Status Solidi RRL 3(7-8), 227-229 (2009), and O. Breitenstein et al. Phys. Status Solidi RRL 4(1), 7-9 (2010). A common factor in these techniques is the acquisition and comparison of two or more images of luminescence generated under different excitation conditions, usually to produce different current flows within the sample cell. Ideally, a series resistance imaging measurement should take less than a second, to keep up with the ˜3,600 wafers per hour throughput of current silicon PV cell lines.

The method disclosed in US 2011/0012636 A1 (hereinafter the ‘'636 method’) is ‘non contact’ in that only optical excitation is applied, with no requirement for electrical contact to the sample cell. This is advantageous in terms of measurement time and the reduced risk of cell breakage, however the technique is purely qualitative: a voltage difference image of a cell is generated that reveals areas with relatively high and low series resistance, but there is no guidance as to how one might quantify the series resistance across the sample cell. On the other hand the methods disclosed in WO 2009/129575 A1 provide quantitative values for series resistance across a sample cell, but electrical contact is required for at least some of the imaging measurements. Furthermore these methods are relatively slow, requiring the acquisition and processing of several images; because interpolation or extrapolation of data is involved, greater accuracy is obtained with more images.

### SUMMARY OF THE INVENTION

It is an object of the present invention to overcome or ameliorate at least one of the disadvantages of the prior art, or to provide a useful alternative. It is an object of a preferred form of the present invention to provide rapid methods for quantifying the spatial variation of series resistance across photovoltaic cells. It is an object of another preferred form of the present invention to provide non-contact methods for quantitatively measuring the spatial variation of series resistance across photovoltaic cells.

In accordance with a first aspect of the present invention there is provided a non-contact method for calculating the reduction in terminal voltage caused by current extraction, ΔVₜ, in a series resistance imaging measurement on a photovoltaic cell having a front surface with one or more bus bars, said method comprising the steps of:
(i) exposing said cell to an illumination pattern with excitation light suitable for generating luminescence from said cell such that a first portion of said front surface receives substantially less illumination intensity than a second portion of said front surface, said first and second portions being on opposite sides of a bus bar;
(ii) measuring a first luminescence signal L_{dark,x} from a first selected region of said front surface within said first portion;
(iii) measuring a second luminescence signal Lₓ from a second selected region of said front surface within said second portion;
(iv) exposing said cell to uniform illumination with said excitation light, and measuring a third luminescence signal L_{oc} from a third selected region of said front surface; and
(v) calculating ΔVₜ using the equation

ΔVₜ=kT/2eln(L_{oc}²/Lₓ*L_{dark,x}).

In certain embodiments the first, second and third selected regions are preferably all equal in area. In other embodiments the first, second and third selected regions are not all equal in area, and the first, second and third luminescence signals are area-averaged. In certain embodiments the third selected region corresponds to the first selected region or to the second selected region. In other embodiments the third selected region corresponds to a combination of the first and second selected regions. In yet other embodiments the third selected region corresponds to the entire cell area.

The illumination pattern is preferably produced using one or more filters selected to attenuate the excitation light and transmit the luminescence. Preferably, the illumination intensity applied to the first portion is zero.

In accordance with a second aspect of the present invention there is provided a non-contact method for calculating the reduction in terminal voltage caused by current extraction, ΔVₜ, in a series resistance imaging measurement on a photovoltaic cell having a front surface with one or more bus bars, said method comprising the steps of:
(i) exposing said cell to a first illumination pattern with excitation light suitable for generating luminescence from said cell such that a first portion of said front surface receives substantially less illumination intensity than a second portion of said front surface, said first and second portions being on opposite sides of a bus bar, and measuring a first luminescence signal L_{dark,x} from a first selected region of said front surface within said first portion;
(ii) exposing said cell to a second illumination pattern, complementary to said first illumination pattern, such that said first portion receives substantially more illumination intensity than said second portion, and measuring a second luminescence signal Lₓ from a second selected region of said front surface within said first portion;
(iii) exposing said cell to substantially uniform illumination with said excitation light, and measuring a third luminescence signal L_{oc} from a third selected region of said front surface; and
(iv) calculating ΔVₜ using the equation

$$Δ {V}_{t} = \frac{kT}{2 e} ln ( \frac{{L}_{oc}^{2}}{{L}_{x} * {L}_{dark , x}} ) .$$

In preferred embodiments the first, second and third selected regions are all equal in area. More preferably, the first, second and third selected regions are the same region. In other embodiments the first, second and third selected regions are not all equal in area, and the first, second and third luminescence signals are area-averaged. In certain embodiments the third selected region corresponds to the entire cell area.

The first and second illumination patterns are preferably produced using one or more filters selected to attenuate the excitation light and transmit the luminescence. Preferably, zero illumination intensity is applied to the first portion in step (i) and to the second portion in step (ii).

In accordance with a third aspect of the present invention there is provided a method for calculating the local current density extracted over the local series resistance, J_{Rs,i}, in a series resistance imaging measurement on a photovoltaic cell having a front surface with one or more bus bars, said method comprising the steps of:
(i) acquiring a first luminescence image of said cell under substantially uniform illumination with excitation light suitable for generating luminescence from said cell;
(ii) acquiring a second luminescence image of said cell under current extraction;
(iii) measuring or estimating a value for the short circuit current density of said cell, J_{sc}; and
(iv) calculating J_{Rs,i} using the equation

$${J}_{Rs , i} = \frac{( {L}_{A , i} - {L}_{B , i} )}{{L}_{A , i}} {J}_{sc}$$

where L_{A,i} and L_{B,i} are the local luminescence intensities in said first and second luminescence images.

Preferably, the second luminescence image is simulated by combining two or more luminescence images acquired when the cell is exposed to patterned illumination with excitation light suitable for generating luminescence from the cell.

In accordance with a fourth aspect of the present invention there is provided a method for quantitatively measuring variations in series resistance across a photovoltaic cell, said method comprising the steps of:
(i) acquiring a qualitative series resistance image of said photovoltaic cell using a combination of two or more images of luminescence generated from said cell by optical excitation, electrical excitation or a combination thereof, said electrical excitation comprising applying a voltage or load across contact terminals of said cell, or injecting current into or extracting current from contact terminals of said cell;
(ii) measuring, estimating or calculating a value for ΔVₜ, the reduction in terminal voltage of said cell caused by current extraction;
(iii) measuring or estimating a value for J_{sc}, the short circuit current density of said cell; and
(iv) combining said ΔVₜ and J_{sc} values with said qualitative series resistance image to calculate absolute series resistance values across said cell.

Preferably, the value for ΔVₜ is calculated from luminescence measurements made during the acquisition of the qualitative series resistance image. More preferably, the value for ΔVₜ is calculated by the method according to the first or second aspect of the present invention. In preferred embodiments the qualitative series resistance image is acquired without making electrical contact to the cell.

In certain embodiments the value for J_{sc} is used to calculate local values for J_{Rs,i} the local current density extracted over the local series resistance, using the equation:

$${J}_{Rs , i} = \frac{( {L}_{A , i} - {L}_{B , i} )}{{L}_{A , i}} {J}_{sc}$$

where L_{A,i} are the local luminescence intensities in an image of luminescence generated from the cell with substantially uniform optical excitation, and L_{B,i} are the local luminescence intensities in an image of luminescence generated from the cell with a combination of substantially uniform optical excitation and current extraction. In other embodiments the value for J_{sc} is used to calculate local values for J_{Rs,i} the local current density extracted over the local series resistance, using the equation:

$${J}_{Rs , i} = \frac{( {L}_{A , i} - {L}_{B , i} )}{{L}_{A , i}} {J}_{sc}$$

where L_{A,i} are the local luminescence intensities in an image of luminescence generated from the cell with substantially uniform optical excitation, and L_{B,i} are the local luminescence intensities in one or more images of luminescence generated from the cell using one or more optical excitation patterns.

In preferred embodiments, local values for the series resistance of the photovoltaic cell, R, are calculated using the equation:

$${R}_{s , i} = \frac{Δ {V}_{Rs , i}}{{J}_{Rs , i}}$$

wherein ΔV_{Rs,i} is calculated using the equation:

ΔV_{Rs,i}=ΔVₜ−ΔV_{d,i}

wherein ΔV_{d,i} values are obtained from the qualitative series resistance image.

In accordance with a fifth aspect of the present invention there is provided a non-contact method for measuring variations in series resistance across a photovoltaic cell having a front surface with one or more bus bars, said method comprising the steps of:
(i) exposing said cell to a first patterned illumination with excitation light suitable for generating luminescence from said cell such that a first portion of said front surface receives substantially less illumination intensity than a second portion of said front surface, said first and second portions being on opposite sides of a bus bar, wherein said first patterned illumination is produced with one or more filters selected to attenuate said excitation light and transmit said luminescence;
(ii) acquiring a first image of luminescence generated from said cell by said first patterned illumination;
(iii) exposing said cell to uniform illumination with said excitation light;
(iv) acquiring a second image of luminescence generated from said cell by said uniform illumination; and
(v) processing said first and second images to determine variations in series resistance across said cell.

Preferably, the first and second images are further processed to determine absolute values of series resistance across the cell.

In certain embodiments, the method further comprises the steps of:
(vi) exposing the cell to a second patterned illumination with the excitation light, the second patterned illumination being complementary to the first patterned illumination and produced with one or more filters selected to attenuate the excitation light and transmit the luminescence;
(vii) acquiring a third image of luminescence generated from the cell by the second patterned illumination; and
(viii) processing the first, second and third images to determine variations in series resistance across the cell.

Preferably, the first, second and third images are further processed to determine absolute values of series resistance across the cell.

The filters are preferably selected to block substantially all of the excitation light.

In accordance with a sixth aspect of the present invention there is provided a non-contact method for identifying conductance defects in a photovoltaic cell precursor having a front surface with a selective emitter structure, said method comprising the steps of:
(i) exposing said precursor to a first patterned illumination with excitation light suitable for generating luminescence from said precursor such that a first portion of said front surface receives substantially less illumination intensity than a second portion of said front surface, said first and second portions being on opposite sides of a section of said selective emitter structure onto which a bus bar is to be deposited, wherein said first patterned illumination is produced with one or more filters selected to attenuate said excitation light and transmit said luminescence;
(ii) acquiring a first image of luminescence generated from said precursor by said first patterned illumination;
(iii) exposing said precursor to uniform illumination with said excitation light;
(iv) acquiring a second image of luminescence generated from said precursor by said uniform illumination; and
(v) processing said first and second images to identify conductance defects in said precursor.

Preferably, the method further comprises the steps of:
(vi) exposing the precursor to a second patterned illumination with the excitation light, the second patterned illumination being complementary to the first patterned illumination and produced with one or more filters selected to attenuate the excitation light and transmit the luminescence;
(vii) acquiring a third image of luminescence generated from the precursor by the second patterned illumination; and
(viii) processing the first, second and third images to identify conductance defects in the precursor.

The filters are preferably selected to block substantially all of the excitation light.

In accordance with a seventh aspect of the present invention there is provided a system when used to implement the method according to any one of the first to sixth aspects of the present invention.

In accordance with an eighth aspect of the present invention there is provided an article of manufacture comprising a computer usable medium having a computer readable program code configured to implement the method according to any one of the first to sixth aspects of the present invention, or to operate the system according to the seventh aspect of the present invention.

### BRIEF DESCRIPTION OF THE DRAWINGS

Benefits and advantages of the present invention will become apparent to those skilled in the art to which this invention relates from the subsequent description of exemplary embodiments, taken in conjunction with the accompanying drawings, in which:

FIGS. 1(a) and 1(b) show in plan view and side view a schematic of a typical photovoltaic cell;

FIG. 2 illustrates various contributions to the series resistance at a given region of a typical photovoltaic cell;

FIGS. 3(a) and 3(b) show spatially inhomogeneous illumination patterns that may be used to generate series resistance images of a photovoltaic cell via non-contact luminescence imaging;

FIGS. 4(a) and 4(b) illustrate the use of long-pass filters to produce inhomogeneous illumination patterns, while allowing luminescence to be measured from both the illuminated and non-illuminated portions;

FIG. 5 illustrates the measurement of luminescence from a non-illuminated portion of a photovoltaic cell when an inhomogeneous illumination pattern is produced with an opaque shutter;

FIG. 6 shows light and dark IV curves for a typical silicon photovoltaic cell;

FIGS. 7(a), 7(b) and 7(c) illustrate the acquisition of luminescence signals useful for the determination of quantitative series resistance data for a photovoltaic cell via non-contact luminescence imaging according to an embodiment of the invention;

FIG. 8 illustrates the acquisition of luminescence signals useful for the determination of quantitative series resistance data for a photovoltaic cell via non-contact luminescence imaging according to another embodiment of the invention;

FIG. 9 shows a quantitative series resistance image of a photovoltaic cell acquired according to an embodiment of the invention; and

FIG. 10 shows in plan view a silicon wafer with a patterned emitter structure.

### DETAILED DESCRIPTION

Preferred embodiments of the invention will now be described, by way of example only, with reference to the accompanying drawings.

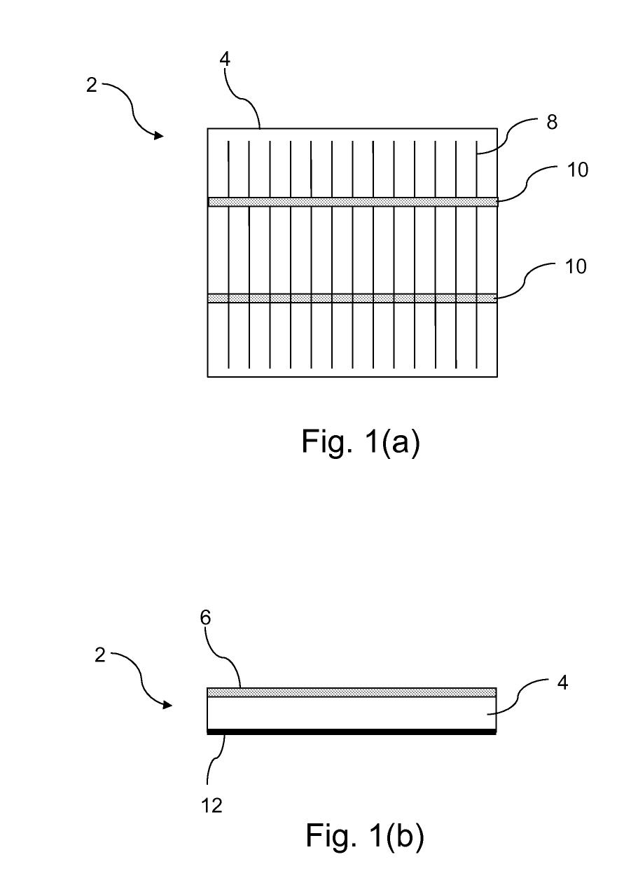

FIGS. 1(a) and 1(b) show in plan view and side view a schematic of a typical PV cell 2 comprising a p-type silicon wafer 4 with an in-diffused n-type emitter layer 6, metal fingers 8 and bus bars 10 on the front surface, and a metal contact layer 12 covering the rear surface.

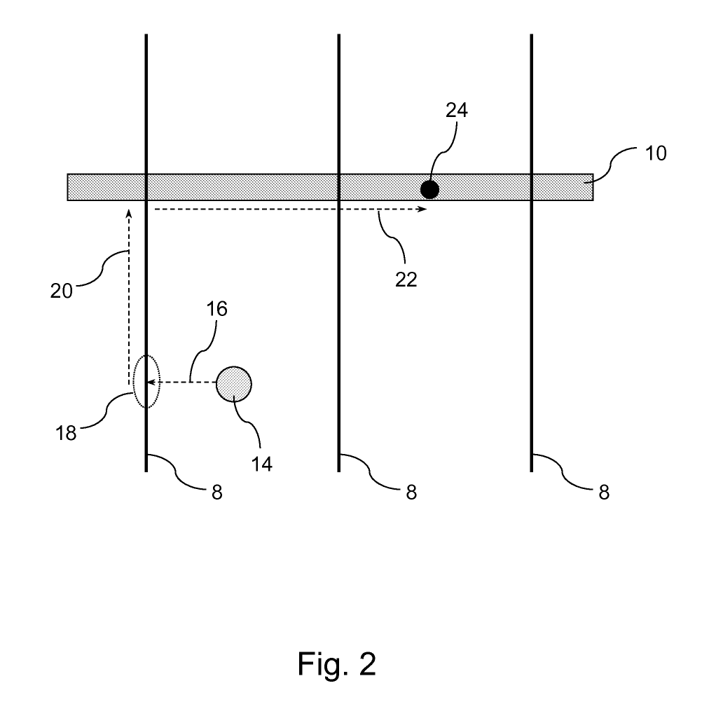

As illustrated in FIG. 2, and recalling that photo-generated currents are transported via the emitter layer to the metal fingers and thence along the fingers and bus bars to the cell terminals, the series resistance at a given cell region 14 is given primarily by the sum of contributions from the emitter resistance 16 between that cell region and the adjacent finger(s), the contact resistance 18 between the emitter layer and the fingers, the resistance 20 along the fingers to the bus bar, and the contact resistance at the rear surface metal contact layer (not shown in FIG. 2). There will also be a contribution from the resistance 22 of the bus bar between the finger and the cell terminal (in operation) or between the finger and the nearest contact pin 24 (in a series resistance measurement), but this contribution will generally be small. Similar factors contribute to the series resistance of PV cells with other metallisation patterns, such as those with metal grids on both surfaces and all-rear-contact cells.

Published PCT application No WO 2007/128060 A1 describes a qualitative method for identifying high series resistance areas of a PV cell, based on a comparison of two images of luminescence generated with different excitation conditions that enables spatial luminescence intensity variations caused by series resistance effects to be distinguished from those caused by carrier lifetime variations. In these images luminescence may for example be generated from the cell by applying a voltage (electroluminescence), or by applying optical excitation (photoluminescence), or by applying optical excitation with simultaneous current extraction from or current injection into the cell terminals; of these, all except the photoluminescence image require electrical contact to be made to the cell and generate significant lateral current flows across the cell. A single luminescence image may suffice for identifying high series resistance regions if spatial intensity variations can be assigned confidently to a series resistance problem rather than carrier lifetime variations. For example a linear higher intensity region along a metal finger in an image of luminescence generated using optical excitation with simultaneous current extraction is highly suggestive of a break in that finger.

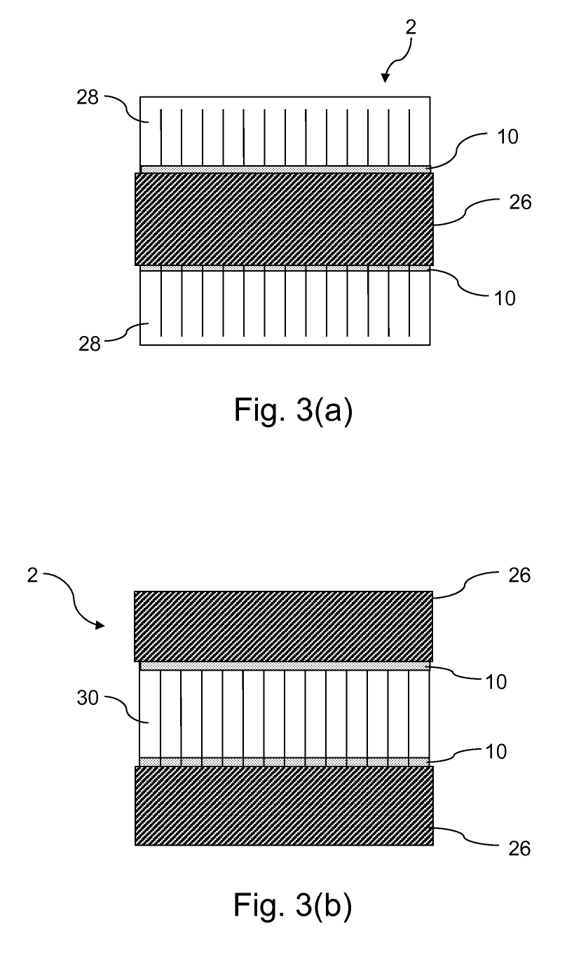

The '636 method is a non-contact variation on this general image comparison method, where lateral currents are made to flow in a PV cell by illuminating the cell surface in a spatially inhomogeneous fashion. With reference to FIG. 3(a), the portion of a PV cell 2 between the bus bars 10 is covered with an opaque shutter or shadow mask 26 such that only the outer portions 28 of the cell are illuminated, and the luminescence from the illuminated portions measured to produce a first luminescence image. As shown in FIG. 3(b) a complementary illumination pattern is applied with two opaque shutters or shadow masks 26 and the luminescence from the illuminated inner cell portion 30 measured to produce a second luminescence image. These two images are then combined to produce a luminescence image of the entire cell that simulates an image of luminescence generated using optical excitation with simultaneous current extraction from the cell terminals. This composite image is then divided by an image of luminescence generated by applying uniform optical excitation to the cell (an ‘open circuit’ photoluminescence image) via pixel-by-pixel calculation of intensity ratios to produce a voltage difference image which is a qualitative indicator of series resistance variations. The step of dividing the simulated current extraction image by the open circuit photoluminescence image is essentially a normalisation step that serves to remove carrier lifetime-related intensity variations, and can be omitted if spatial intensity variations can be assigned confidently to a series resistance problem. The actual illumination intensity in the so-called non-illuminated portions does not need to be zero; it just needs to be significantly lower (e.g. at least 10 times less) than the illumination intensity in the illuminated portions so that the resulting spatial variations in carrier density cause significant lateral current flows in the sample cell. With this proviso, we will continue to use the terms ‘non-illuminated portion’ and ‘illuminated portion’ in this specification.

Turning now to quantitative considerations, series resistance (R_{S}) generally varies significantly across the area of a PV cell, and knowledge of the local current density Jᵢ at position i across a cell is normally required for an accurate determination of the local series resistance, i.e. the series resistance at position i, R_{S,i}. In an illuminated PV cell Jᵢ is given as: Jᵢ=J_{light}−J_{d,i}(Vᵢ), where J_{light} is the light-generated current (a global quantity) which to a good approximation is linear in the illumination intensity, and J_{d,i}(V) is the local diode dark current density at position i. J_{d,i}(V) depends on the local diode voltage at position i (Vᵢ) and on a number of other parameters, including the local diode saturation current and the local diode ideality factor, that vary across the area of a cell in a generally unknown manner.

As explained in WO 2009/129575 A1, a fundamental problem with several prior art methods for measuring R_{S,i} is the use of a global estimate for the unknown local diode properties, which leads to inaccuracies because the local diode properties generally vary substantially across a PV cell. WO 2009/129575 A1 describes a quantitative method that avoids this problem, based on the acquisition of two or more images of luminescence generated using optical excitation with or without extraction of current from the cell, and optionally electroluminescence images as well. The fundamental idea is to find two different operating conditions A and B (with different terminal voltages and/or different illumination intensities) of a sample PV cell that produce the same local luminescence signal on a pixel-by-pixel basis, then use that information to calculate local R_{S} values. However while this method yields quantitative results, electrical contact is required for at least some of the imaging measurements, and furthermore it is relatively slow because it requires the acquisition and processing of several images.

The luminescence intensity at a given pixel i of a luminescence image, Lᵢ, depends exponentially on the local diode voltage in the corresponding cell region, V_{d,i} according to the equation

$${L}_{i} = {C}_{i} exp ( \frac{e {V}_{d , i}}{kT} ) \qquad ( 1 )$$

where e is the electronic charge, k is Boltzmann's constant, T is temperature and Cᵢ is a local calibration constant. The local calibration constant can be eliminated from the analysis by obtaining two images with different excitation conditions. In an example of particular relevance to series resistance measurements, the pixel-by-pixel ratio of two luminescence images, one generated with uniform optical excitation (an open circuit photoluminescence image) and the other a current extraction image either generated with optical excitation with simultaneous current extraction or simulated by the '636 method as described above, provides a measure of the local reduction in diode voltage due to the current extraction for pixel i, ΔV_{d,i} via the equation

$$\begin{matrix}Δ {V}_{d , i} = {V}_{d , A , i} - {V}_{d , B , i} \\ = \frac{kT}{e} ln ( \frac{{L}_{A , i}}{{L}_{B , i}} )\end{matrix} \qquad ( 2 )$$

where the subscript A refers to the open circuit photoluminescence image and the subscript B refers to the current extraction image, actual or simulated. As well as this drop in diode voltage ΔV_{d,i}, the current extraction also causes a voltage drop between the diode and the terminal, i.e. over the series resistance, ΔV_{Rs,i}. Therefore the voltage drop over the diode varies strongly with series resistance and is the main source of information on local series resistance, i.e. variations in series resistance across the sample. The task now is to extract quantitative series resistance data from this information. In particular, we show how the '636 method can be quantified while still avoiding contacting the sample cell, advantageous for minimising cell breakage, and without requiring additional imaging steps, advantageous for measurement speed.

The local series resistance determines the local voltage drop over that series resistance, ΔV_{Rs,i} and thereby the voltage V_{t,B} between the cell terminals under current extraction, as represented by the equation:

ΔV_{Rs,i}=V_{d,B,i}−V_{t,B} (3)

With V_{oc} representing the open circuit voltage, we define the reduction in the terminal voltage caused by the current extraction, ΔVₜ, as:

ΔVₜ=V_{oc}−V_{t,B} (4)

We assume that V_{oc} is equivalent to the diode voltage V_{d,A,i} in all areas of the open circuit photoluminescence image, so equations (2) to (4) can be combined to yield:

ΔV_{Rs,i}=ΔVₜ−ΔV_{d,i} (5)

The voltage difference ΔV_{d,i} is obtained for each pixel from the luminescence intensity ratio according to equation (2), but it remains to determine ΔVₜ. In some embodiments ΔVₜ is measured directly by making contact with the terminals during both luminescence imaging measurements (i.e. optical excitation with and without current extraction); since this is simply a voltage measurement the contacting requirements are less stringent than for electroluminescence or current-voltage (IV) measurements, or for photoluminescence measurements with simultaneous current injection or extraction, which require a power supply, a source measurement unit or an electric load, and generally require elaborate contacting schemes to ensure uniform current injection or extraction. In other embodiments photoluminescence measurements with simultaneous current injection or extraction can be acquired during IV testing, when the sample cell is being contacted anyway.

For preference however no electrical contact is made, in which case we either need to calculate ΔVₜ or use an empirical value. In one empirical approach, we note that the same value of ΔVₜ is likely to apply to similar cells, for example cells from a given production line. Therefore a ΔVₜ value measured directly on one cell, or an average value measured from a selection of cells, can be applied to all cells from the production line. In another empirical approach a representative ΔVₜ value can be obtained by matching the resulting average series resistance with the global series resistance, the latter determined for example from analysis of a dark IV curve, a light IV curve, a Suns-Voc curve, or any combination thereof; in effect ΔVₜ is used as an adjustable parameter that is varied to get the best fit between the global series resistance and the qualitative spatially resolved data.

Once a ΔVₜ value has been determined, allowing ΔV_{Rs,i} to be obtained via eqn (5), the local series resistance R_{s,i} is given by:

$${R}_{s , i} = \frac{Δ {V}_{Rs , i}}{{J}_{Rs , i}} \qquad ( 6 )$$

where J_{Rs,i}, the local current density extracted over the local series resistance, also needs to be calculated.

We will now describe methods for calculating or estimating ΔVₜ and J_{Rs,i} to enable calculation of quantitative R_{s,i} data via eqn (6).

Turning firstly to J_{Rs,i}, in one example method we begin with the ideal diode equation for the diode dark current density J_{d,i}(V_{d,i}):

$${J}_{d , i} ( {V}_{d , i} ) = {J}_{0} exp ( \frac{e {V}_{d , i}}{kT} ) \qquad ( 7 )$$

where J₀ is the dark saturation current density. The current density extracted over the series resistance, J_{Rs,i} is calculated as the variation in dark current density between V_{d,i}=V_{oc} (open circuit) and V_{d,i}=V_{oc}−ΔV_{d,i} (current extraction), i.e. J_{Rs,i}=J_{d,i}(V_{oc})−J_{d,i}(V_{oc}−ΔV_{d,i}). ΔV_{d,i} is obtained from the luminescence intensity ratio (eqn (2)), but we still require Jₒ and the open circuit voltage V_{oc}. In one example we choose V_{oc}=620 mV and J₀=1.541 e-12 A/cm², typical values for silicon cells, which is equivalent to a short circuit current density of J_{sc}=35 mA/cm² for that open circuit voltage.

In a second example method for calculating J_{Rs,i} we assume that the reduction in luminescence signal between an open circuit photoluminescence image and a photoluminescence image acquired with current extraction, actual or simulated, is proportional to the extracted current, i.e.

$${J}_{Rs , i} = \frac{( {L}_{A , i} - {L}_{B , i} )}{{L}_{A , i}} {J}_{sc} \qquad ( 8 )$$

In this equation, as in eqn (2), the subscripts A and B refer to the open circuit photoluminescence image and the photoluminescence image acquired with current extraction respectively. For example if the luminescence signal in a pixel i of image B is only 10% of the signal from the corresponding pixel of image A, then 90% of the short circuit current density has been extracted from the corresponding cell region. This assumption is based on the fact that with a unity ideality factor the luminescence signal is proportional to the dark current density; eqn (8) shows that the only quantity that needs to be known or estimated is the short circuit current density J_{sc}, which in this analysis is assumed to be uniform across the cell, i.e. independent of position i.

It turns out that these two example methods are equivalent. This can be demonstrated as follows, beginning with the equation J_{Rs,i}=J_{d,i}(V_{oc})−J_{d,i}(V_{oc}−ΔV_{d,i}) from the first example method and transforming it using eqns (7) and (2) to arrive at eqn (8) from the second example method:

$$\begin{matrix}{J}_{Rs , i} = {J}_{d , i} ( {V}_{oc} ) - {J}_{d , i} ( {V}_{oc} - Δ {V}_{d , i} ) \\ = {J}_{SC} - {J}_{0} exp ( \frac{e}{kT} [ {V}_{oc} - Δ {V}_{d , i} ] ) \\ = {J}_{SC} - \frac{{J}_{0} exp ( \frac{e}{kT} {V}_{oc} )}{exp ( \frac{e}{kT} Δ {V}_{d , i} )} \\ = {J}_{SC} - \frac{{J}_{SC}}{\frac{{L}_{A , i}}{{L}_{B , i}}} \\ = {J}_{SC} ( \frac{{L}_{A , i} - {L}_{B , i}}{{L}_{A , i}} )\end{matrix}$$

The need to select a V_{oc} value in the first example method arises from the need to obtain J₀ to be able to calculate the diode dark current density. However the J₀ value is obtained from the ideal diode equation for a specific J_{sc}; the choice of V_{oc} is therefore irrelevant because a higher V_{oc} will result in a lower J₀ but in the same extracted current for any selected V_{oc} value. In summary then, once the luminescence images A and B have been acquired, values for J_{Rs,i} across a sample cell can be calculated via eqn (8) using a global value for the short circuit current density J_{sc}. For silicon cells, a typical value is J_{sc}=35 mA/cm². In other embodiments J_{sc} is measured directly during IV testing, or an empirical value used, such as the average value for a large number of similar cells in production.

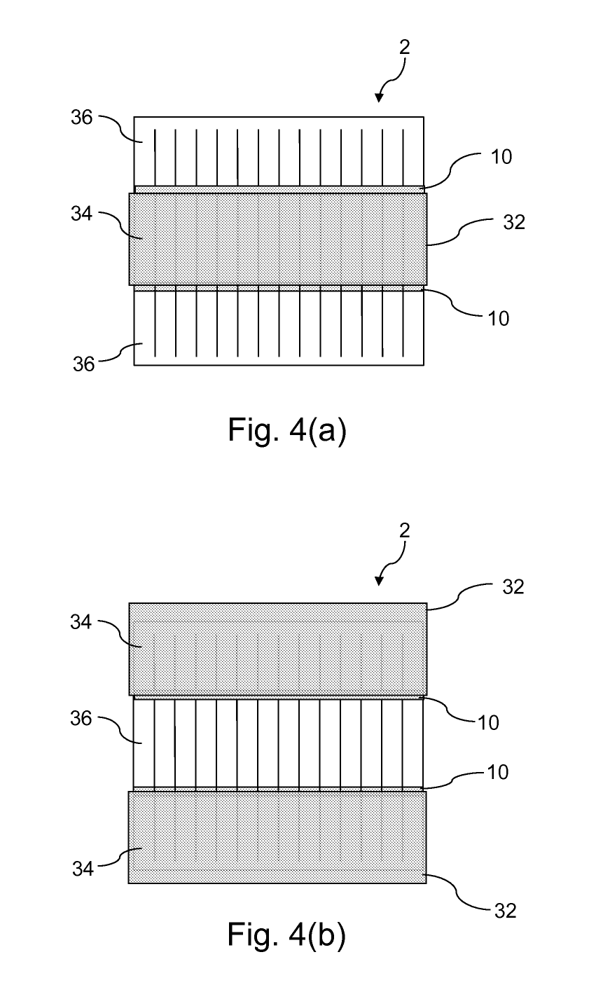

Turning now to ΔVₜ, the reduction in terminal voltage caused by current extraction, in preferred embodiments this quantity is obtained in non-contact fashion from a series of luminescence measurements acquired with patterned illumination. Preferably, these measurements are made during a series of luminescence imaging measurements used to obtain qualitative series resistance data, such as in the '636 method, thereby enabling the data to be quantified while still avoiding making electrical contact with the cell and without requiring additional exposures or images. Our preferred method requires the measurement of luminescence from selected non-illuminated (or significantly less intensely illuminated) portions; this is facilitated by generating the illumination patterns using one or more filters, such as long-pass filters or band-pass filters, selected to block the excitation light but transmit the luminescence. As illustrated in FIGS. 4(a) and 4(b), long-pass filters 32 substantially attenuate the excitation light to produce non-illuminated portions 34 and illuminated portions 36 of a cell 2 on either side of the bus bars 10, yet substantially transmit the luminescence generated by lateral current flow and injection of carriers from the illuminated portions. As described in published PCT patent application No WO 2010/130013 A1, charge carriers generated in an illuminated portion can be transported readily into a non-illuminated portion via the emitter layer, where they can recombine radiatively to produce a luminescence signal from another portion that receives no (or significantly less) illumination. It will be appreciated that the complementary illumination patterns shown in FIGS. 4(a) and 4(b), like those shown in FIGS. 3(a) and 3(b) in the context of the '636 method, allow one to simulate an image of luminescence generated using optical excitation with simultaneous current extraction, for the purpose of acquiring a qualitative series resistance image of a PV cell, or for calculating J_{Rs,i} values from eqn (8). Advantageously, the long-pass filters facilitate the measurement of luminescence signals from the non-illuminated portions as well as the illuminated portions. As will be seen, such signals provide extra information that enables us to calculate a value for ΔVₜ.

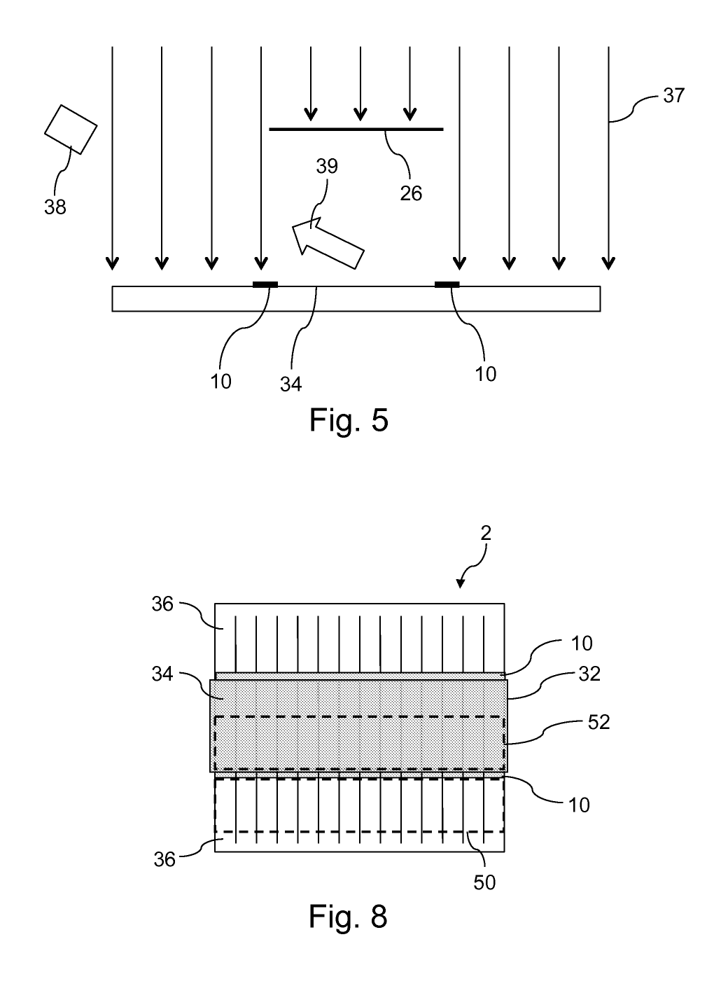

As shown in FIG. 5 it is of course possible to measure luminescence from a cell portion 34 shadowed from the excitation light 37 by an opaque shutter 26, if there is sufficient spacing between the shutter and the cell for a camera or other detector 38 to access the luminescence 39. However since the illumination pattern should be aligned with the bus bars 10, this spacing greatly tightens the alignment tolerance between the shutter and the cell, and a well-collimated light source would be required to maintain a sharp border of the shaded portion. Furthermore since many cell designs have a metal contact layer on the back surface, it is often not possible to position the excitation source and detector on opposite sides of a cell, a configuration that might otherwise be used for measuring luminescence from a shadowed portion.

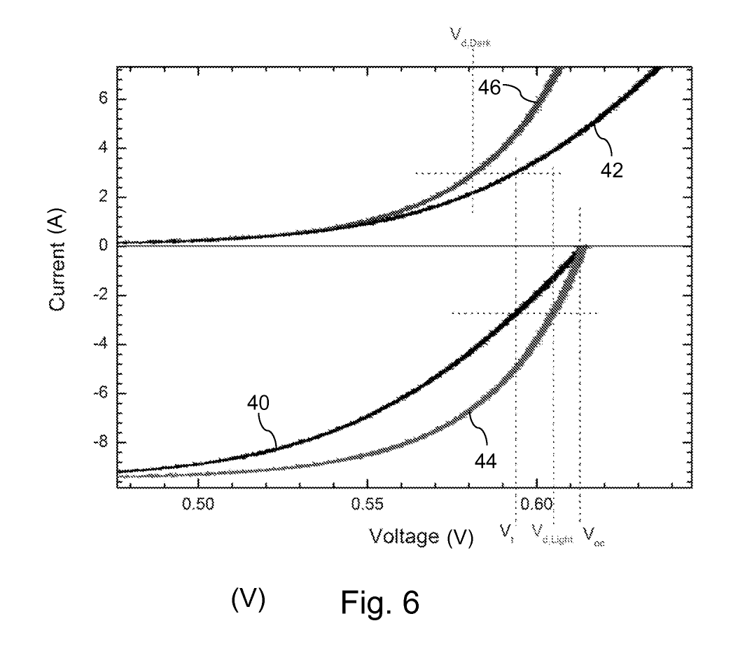

FIG. 6 shows a light IV curve 40 and a dark IV curve 42 of a typical silicon PV cell, i.e. the current as a function of terminal voltage under ˜1 Sun illumination and without illumination respectively, along with an implied light IV curve 44 (current as a function of diode voltage under ˜1 Sun illumination) and an implied dark IV curve 46 (current as a function of diode voltage without illumination). The dark IV curve was measured experimentally, and used to simulate the other three curves under the assumption that series resistance is independent of illumination conditions, i.e. operating point. The dotted vertical lines indicate the various voltages relevant to our analysis. From left to right, these are:
(i) V_{d,dark}: the diode voltage under current injection (carrier transport) into the non-illuminated portion(s) from the illuminated cell portion(s);
(ii) Vₜ: the terminal voltage under current extraction, which is the same for the illuminated and non-illuminated cell portions;
(iii) V_{d,light}: the diode voltage under current extraction (carrier transport) from the illuminated portion(s) into the non-illuminated cell portion(s);
(iv) V_{oc}: the open circuit voltage (i.e. terminal voltage without current extraction).

With the assumption that series resistance is independent of the illumination conditions, the voltage drop over the series resistance in the non-illuminated portion (Vₜ−V_{d,dark}) is identical to the voltage drop over the series resistance in the illuminated portion (V_{d,light}−Vₜ), since the current extracted from the illuminated portion will be equal to the current flowing into the non-illuminated portion. Under this assumption, the terminal voltage Vₜ is related to the average value of the luminescence signals (expressed as voltages, see eqn (1)) from the illuminated and non-illuminated portions:

$${V}_{t} = \frac{{V}_{d , light} + {V}_{d , dark}}{2} \qquad ( 9 )$$

Although conversion of a luminescence signal into a voltage or vice versa requires knowledge of a calibration constant C (see eqn (1)), we only require the voltage difference ΔVₜ defined above in eqn (4).

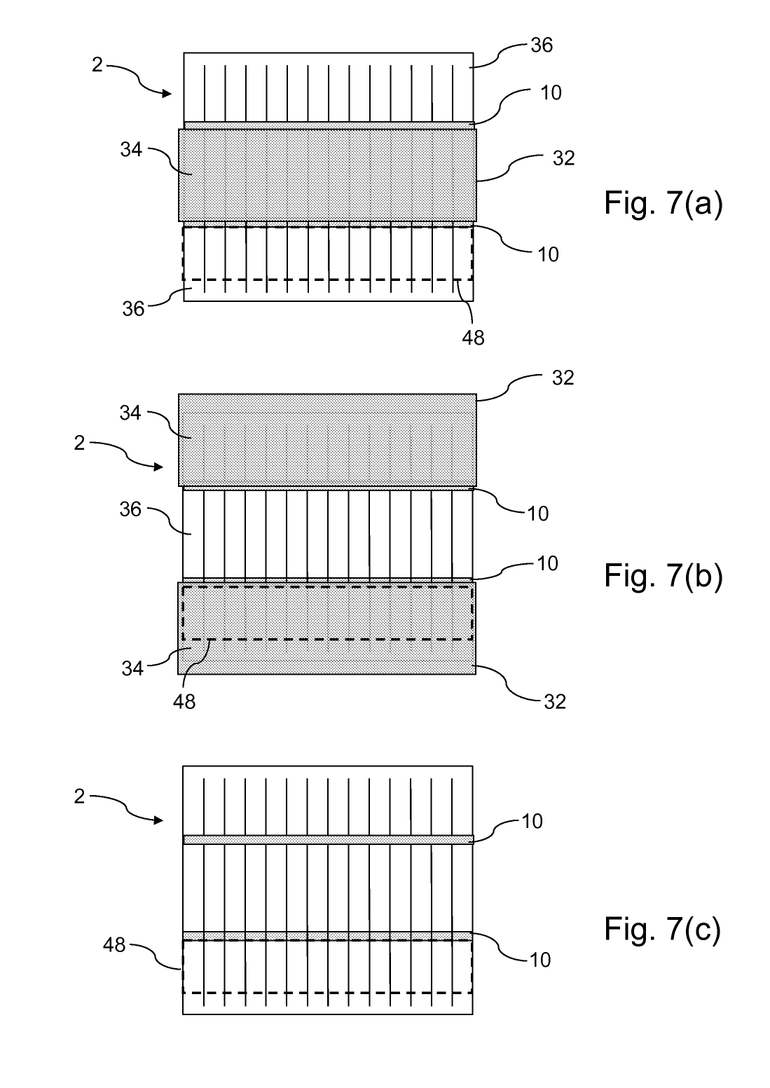

Turning now to FIGS. 7(a), 7(b) and 7(c), in one embodiment of the invention we extend known qualitative series resistance imaging methods by exposing a PV cell 2 to complementary illumination patterns using long-pass filters 32 to define illuminated and non-illuminated portions 36 and 34 (FIGS. 7(a) and 7(b)), and to uniform illumination (FIG. 7(c)), and select a cell region 48 for which we define area-averaged luminescence signals as follows: L_{oc} as the average or total signal from that region in the open circuit photoluminescence image (i.e. uniform illumination across the cell) as shown in FIG. 7(c); Lₓ as the average or total signal from that region when under illumination as shown in FIG. 7(a); and L_{dark,x} as the average or total signal from that region under the complementary illumination pattern as shown in FIG. 7(b). For that particular region 48, we can use equations (1), (4) and (9) to obtain

$$Δ {V}_{t} = \frac{kT}{2 e} ln ( \frac{{L}_{oc}^{2}}{{L}_{x} * {L}_{dark , x}} ) \qquad ( 10 )$$

The ΔVₜ value obtained from this equation is then fed into the series resistance calculations via equation (5). Note that the respective excitation intensities applied to the illuminated and non-illuminated portions should be the same for each of the three exposures.

In the particular example shown in FIGS. 7(a) to 7(c) the selected region 48 is identical for all three measurements L_{oc}, Lₓ and L_{dark,x}. While this is preferable it is not essential, as different regions can be selected for each measurement provided the luminescence signals from each region are area-averaged. For example the selected region in FIG. 7(c) may correspond to the entire cell area. Each region may include several non-contiguous sub-regions provided the illumination conditions are the same for all sub-regions in each imaging step. Preferably the selected region(s) is/are close to a bus bar as shown in FIGS. 7(a) to 7(c), to maximise the current flow caused by the inhomogeneous illumination. In another embodiment area-averaged luminescence signals from several selected regions are used to obtain an average or median ΔVₜ value, for higher accuracy.

In an alternative embodiment illustrated in FIG. 8, L_{dark,x} and Lₓ are obtained from a single patterned exposure of a PV cell 2, where Lₓ is the average or total luminescence signal from a selected region 50 in the illuminated portion 36 and L_{dark,x} is the average or total luminescence signal from a corresponding region 52 in the non-illuminated portion 34 on the opposite side of a bus bar; an analogous analysis leads to the same equation (10) for ΔVₜ, where PL_{oc} is obtained as the average or total luminescence signal from a selected cell region, such as area 50, or 52 or the entire cell area, when the cell is illuminated uniformly. The two regions 50 and 52 are preferably equal in size, but may be different provided the various luminescence signals are area-averaged. Similarly to the previous embodiment, the excitation intensity applied to the illuminated portions should be the same for each exposure.

It may turn out that for a given cell design, there are some regions that yield ΔVₜ most accurately. These regions may be determined empirically by comparing ΔVₜ values calculated from the above analysis with actual values measured at the terminals.

It will be appreciated that the luminescence measurements utilised in the above-described methods for calculating ΔVₜ via eqn (10) (and therefore ΔV_{Rs,i} via eqn (5)) and J_{Rs,i} via eqn (8) can be made concurrently with the acquisition of the luminescence images required for producing a qualitative series resistance image. Since the quantification procedure does not require any additional images or exposures, it has essentially no impact on measurement speed. Furthermore it is possible to quantify a series resistance image in a non-contact manner.

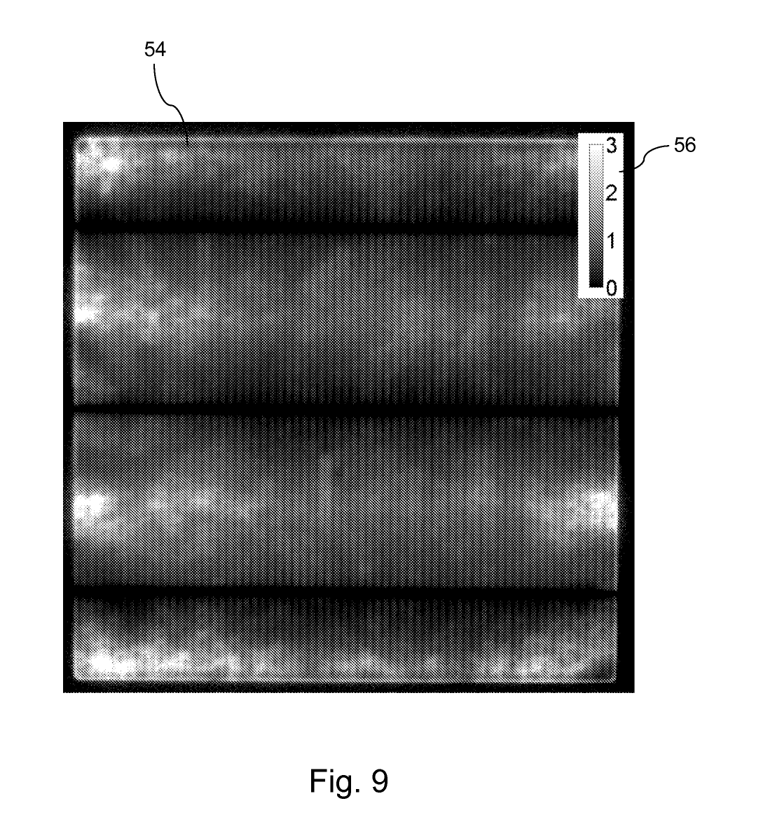

FIG. 9 shows a series resistance image 54 of a multicrystalline PV cell with three bus bars, acquired using the '636 method where the illumination patterns were generated using long-pass filters as described above with reference to FIGS. 4(a) and 4(b). Parts of the cell with higher series resistance are clearly shown as brighter regions in the image. Using ΔVₜ and J_{sc} values as described above, this qualitative series resistance information was quantified as shown by the scale bar 56, in units of Ohm.cm². It will be appreciated that the lateral variations in absolute series resistance across the cell could be presented in other forms, such as in tabular or matrix form.

The measurement of luminescence from non-illuminated portions of a photovoltaic cell subjected to patterned illumination with excitation light, preferably facilitated with long-pass filters as described above with reference to FIGS. 4(a) and 4(b), also enables alternative methods for obtaining qualitative series resistance images. For example instead of combining images of luminescence emitted from illuminated portions with excitation from complementary illumination patterns to simulate a photoluminescence image with simultaneous current extraction, one could combine images of luminescence emitted from the non-illuminated portions to simulate an electroluminescence image with simultaneous current injection. This simulated current injection image could then be normalised with a standard electroluminescence image or an open circuit photoluminescence image to remove carrier lifetime-related intensity variations, noting that the procedure would not be non-contact if the electroluminescence image were used. It is also possible to obtain a qualitative series resistance image with only two exposures, one with patterned illumination and one with uniform illumination. For example with reference to FIG. 8 one can apply patterned illumination to a photovoltaic cell 2 and acquire an image of the luminescence emitted from both the illuminated and non-illuminated portions 36, 34, and acquire an open circuit photoluminescence image with uniform illumination as shown in FIG. 7(c). The non-illuminated and illuminated parts of the first image are then treated separately with the open circuit photoluminescence image to produce a qualitative series resistance image. Qualitative series resistance images obtained by these alternative procedures can also be quantified by the above-described methods.

Returning now to the assumption that the series resistance of a cell is independent of the illumination conditions, in reality the series resistance in a non-illuminated cell (measured for example by electroluminescence techniques or by analysis of a dark IV curve) is significantly lower than the series resistance in an illuminated cell, see for example the discussion in D. Pysch et al. Solar Energy Materials & Solar Cells 91 (2007) 1698-1706. This discrepancy may be accounted for by introducing a constant scaling factor into the above analysis, to improve the accuracy of the quantitative series resistance values.

Our methods for obtaining quantitative spatially resolved series resistance data have been described in terms of PV cells with two bus bars on the front surface, which is the most common design, but they are also applicable to cell designs with greater or fewer bus bars.

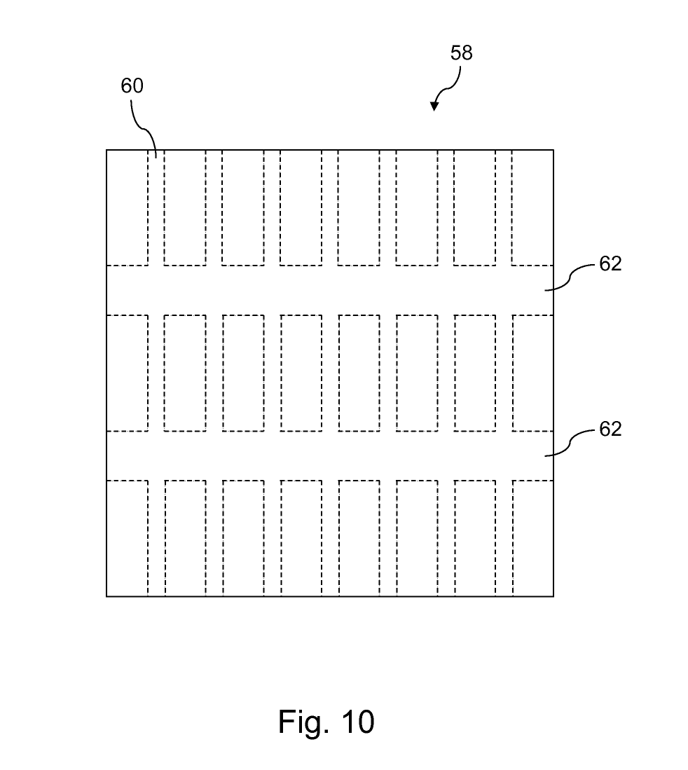

While most commercially available silicon PV cells have a uniform emitter layer 6 as shown in FIG. 1, certain high efficiency cell designs have a selective emitter structure with highly doped regions under the metallisation lines only, and light doping elsewhere for reduced blue absorption. For example FIG. 10 shows a precursor selective emitter cell 58 with a pattern of highly doped regions 60 onto which bus bars and fingers will be deposited in a subsequent metallisation step. Since metallisation, e.g. via screen printing of silver-containing paste, is the most expensive step in PV cell production, it would be advantageous to remove wafers with conductance defects in the selective emitter structure, caused for example by cracks or faulty deposition, before metallisation. Such defects may be identified using the above-described non-contact series resistance imaging methods, qualitative or quantitative, adapted such that the illuminated and non-illuminated portions in a patterned exposure are arranged on either side of selective emitter sections 62 onto which the bus bars are to be deposited.

Apart from the quantification of series resistance images, a further aspect of potential value to PV cell manufacturers is the application of image processing, in particular image recognition algorithms adapted to identify and report patterns of excessively high series resistance that may be associated with typical series resistance problems, preferably with reference to a library of series resistance images of cells with known defects. Examples of typical patterns that can be recognised include patterns of the cell-carrying belt that may suggest a process problem with the metal contact firing furnace, edge isolation issues, and broken or poorly contacting fingers. Image processing algorithms can report the type and severity of common series resistance problems, and could also suggest to an operator how the identified problems could be fixed.

Although the invention has been described with reference to specific examples, it will be appreciated by those skilled in the art that the invention may be embodied in many other forms.

1. A non-contact method for calculating the reduction in terminal voltage caused by current extraction, ΔVₜ, in a series resistance imaging measurement on a photovoltaic cell having a front surface with one or more bus bars, said method comprising the steps of:
(i) exposing said cell to an illumination pattern with excitation light suitable for generating luminescence from said cell such that a first portion of said front surface receives substantially less illumination intensity than a second portion of said front surface, said first and second portions being on opposite sides of a bus bar;
(ii) measuring a first luminescence signal L_{dark,x} from a first selected region of said front surface within said first portion;
(iii) measuring a second luminescence signal Lₓ from a second selected region of said front surface within said second portion;
(iv) exposing said cell to uniform illumination with said excitation light, and measuring a third luminescence signal L_{oc} from a third selected region of said front surface; and
(v) calculating ΔVₜ using the equation
$$Δ {V}_{t} = \frac{kT}{2 e} ln ( \frac{{L}_{oc}^{2}}{{L}_{x} * {L}_{dark , x}} ) .$$

2. A method according to claim 1, wherein said first, second and third selected regions are all equal in area.

3. A method according to claim 1, wherein said first, second and third selected regions are not all equal in area, and said first, second and third luminescence signals are area-averaged.

4. A method according to claim 1, wherein said third selected region corresponds to said first selected region or to said second selected region.

5. A method according to claim 3, wherein said third selected region corresponds to a combination of said first and second selected regions.

6. A method according to claim 3, wherein said third selected region corresponds to the entire cell area.

7. A method according to claim 1, wherein said illumination pattern is produced using one or more filters selected to attenuate said excitation light and transmit said luminescence.

8. A method according to claim 1, wherein the illumination intensity applied to said first portion is zero.

9. A non-contact method for calculating the reduction in terminal voltage caused by current extraction, ΔVₜ, in a series resistance imaging measurement on a photovoltaic cell having a front surface with one or more bus bars, said method comprising the steps of:
(i) exposing said cell to a first illumination pattern with excitation light suitable for generating luminescence from said cell such that a first portion of said front surface receives substantially less illumination intensity than a second portion of said front surface, said first and second portions being on opposite sides of a bus bar, and measuring a first luminescence signal L_{dark,x} from a first selected region of said front surface within said first portion;
(ii) exposing said cell to a second illumination pattern, complementary to said first illumination pattern, such that said first portion receives substantially more illumination intensity than said second portion, and measuring a second luminescence signal Lₓ from a second selected region of said front surface within said first portion;
(iii) exposing said cell to substantially uniform illumination with said excitation light, and measuring a third luminescence signal L_{oc} from a third selected region of said front surface; and
(iv) calculating ΔVₜ using the equation
$$Δ {V}_{t} = \frac{kT}{2 e} ln ( \frac{{L}_{oc}^{2}}{{L}_{x} * {L}_{dark , x}} ) .$$

10. A method according to claim 9, wherein said first, second and third selected regions are all equal in area.

11. A method according to claim 10, wherein said first, second and third selected regions are the same region.

12. A method according to claim 9, wherein said first, second and third selected regions are not all equal in area, and said first, second and third luminescence signals are area-averaged.

13. A method according to claim 12, wherein said third selected region corresponds to the entire cell area.

14. A method according to claim 1, wherein said first and second illumination patterns are produced using one or more filters selected to attenuate said excitation light and transmit said luminescence.

15. A method according to claim 1, wherein zero illumination intensity is applied to said first portion in step (i) and to said second portion in step (ii).

16. A method for calculating the local current density extracted over the local series resistance, J_{Rs,i} in a series resistance imaging measurement on a photovoltaic cell having a front surface with one or more bus bars, said method comprising the steps of:
(i) acquiring a first luminescence image of said cell under substantially uniform illumination with excitation light suitable for generating luminescence from said cell;
(ii) acquiring a second luminescence image of said cell under current extraction;
(iii) measuring or estimating a value for the short circuit current density of said cell, J_{sc}; and
(iv) calculating J_{Rs,i} using the equation
$${J}_{Rs , i} = \frac{( {L}_{A , i} - {L}_{B , i} )}{{L}_{A , i}} {J}_{sc}$$
where L_{A,i} and L_{B,i} are the local luminescence intensities in said first and second luminescence images.

17. A method according to claim 16, wherein said second luminescence image is simulated by combining two or more luminescence images acquired when said cell is exposed to patterned illumination with excitation light suitable for generating luminescence from said cell.

18. A method for quantitatively measuring variations in series resistance across a photovoltaic cell, said method comprising the steps of:
(i) acquiring a qualitative series resistance image of said photovoltaic cell using a combination of two or more images of luminescence generated from said cell by optical excitation, electrical excitation or a combination thereof, said electrical excitation comprising applying a voltage or load across contact terminals of said cell, or injecting current into or extracting current from contact terminals of said cell;
(ii) measuring, estimating or calculating a value for ΔVₜ, the reduction in terminal voltage of said cell caused by current extraction;
(iii) measuring or estimating a value for J_{sc}, the short circuit current density of said cell; and
(iv) combining said ΔVₜ and J_{sc} values with said qualitative series resistance image to calculate absolute series resistance values across said cell.

19. A method according to claim 18, wherein said value for ΔVₜ is calculated from luminescence measurements made during the acquisition of said qualitative series resistance image.

20. A method according to claim 18, wherein said value for ΔVₜ is calculated by the method according to claim 1.

21. A method according to claim 18, wherein said qualitative series resistance image is acquired without making electrical contact to said cell.

22. A method according to claim 18, wherein said value for J_{sc} is used to calculate local values for J_{Rs,i} the local current density extracted over the local series resistance, using the equation:
$${J}_{Rs , i} = \frac{( {L}_{A , i} - {L}_{B , i} )}{{L}_{A , i}} {J}_{sc}$$
where L_{A,i} are the local luminescence intensities in an image of luminescence generated from said cell with substantially uniform optical excitation, and L_{B,i} are the local luminescence intensities in an image of luminescence generated from said cell with a combination of substantially uniform optical excitation and current extraction.

23. A method according to claim 18, wherein said value for J_{sc} is used to calculate local values for J_{Rs,i} the local current density extracted over the local series resistance, using the equation:
$${J}_{Rs , i} = \frac{( {L}_{A , i} - {L}_{B , i} )}{{L}_{A , i}} {J}_{sc}$$
where L_{A,i} are the local luminescence intensities in an image of luminescence generated from said cell with substantially uniform optical excitation, and L_{B,i} are the local luminescence intensities in one or more images of luminescence generated from said cell using one or more optical excitation patterns.

24. A method according to claim 22, wherein local values for the series resistance of said photovoltaic cell, R_{s,i} are calculated using the equation:
$${R}_{s , i} = \frac{Δ {V}_{Rs , i}}{{J}_{Rs , i}}$$
wherein ΔV_{Rs,i} is calculated using the equation:
ΔV_{Rs,i}=ΔVₜ−ΔV_{d,i}
wherein ΔV_{d,i} values are obtained from said qualitative series resistance image.

25. A non-contact method for measuring variations in series resistance across a photovoltaic cell having a front surface with one or more bus bars, said method comprising the steps of:
(i) exposing said cell to a first patterned illumination with excitation light suitable for generating luminescence from said cell such that a first portion of said front surface receives substantially less illumination intensity than a second portion of said front surface, said first and second portions being on opposite sides of a bus bar, wherein said first patterned illumination is produced with one or more filters selected to attenuate said excitation light and transmit said luminescence;
(ii) acquiring a first image of luminescence generated from said cell by said first patterned illumination;
(iii) exposing said cell to uniform illumination with said excitation light;
(iv) acquiring a second image of luminescence generated from said cell by said uniform illumination; and
(v) processing said first and second images to determine variations in series resistance across said cell.

26. A method according to claim 25, wherein said first and second images are further processed to determine absolute values of series resistance across said cell.

27. A method according to claim 25, further comprising the steps of:
(vi) exposing said cell to a second patterned illumination with said excitation light, said second patterned illumination being complementary to said first patterned illumination and produced with one or more filters selected to attenuate said excitation light and transmit said luminescence;
(vii) acquiring a third image of luminescence generated from said cell by said second patterned illumination; and
(viii) processing said first, second and third images to determine variations in series resistance across said cell.

28. A method according to claim 27, wherein said first, second and third images are further processed to determine absolute values of series resistance across said cell.

29. A method according to claim 25, wherein said filters are selected to block substantially all of said excitation light.

30. A non-contact method for identifying conductance defects in a photovoltaic cell precursor having a front surface with a selective emitter structure, said method comprising the steps of:
(i) exposing said precursor to a first patterned illumination with excitation light suitable for generating luminescence from said precursor such that a first portion of said front surface receives substantially less illumination intensity than a second portion of said front surface, said first and second portions being on opposite sides of a section of said selective emitter structure onto which a bus bar is to be deposited, wherein said first patterned illumination is produced with one or more filters selected to attenuate said excitation light and transmit said luminescence;
(ii) acquiring a first image of luminescence generated from said precursor by said first patterned illumination;
(iii) exposing said precursor to uniform illumination with said excitation light;
(iv) acquiring a second image of luminescence generated from said precursor by said uniform illumination; and
(v) processing said first and second images to identify conductance defects in said precursor.

31. A method according to claim 30, further comprising the steps of:
(vi) exposing said precursor to a second patterned illumination with said excitation light, said second patterned illumination being complementary to said first patterned illumination and produced with one or more filters selected to attenuate said excitation light and transmit said luminescence;
(vii) acquiring a third image of luminescence generated from said precursor by said second patterned illumination; and
(viii) processing said first, second and third images to identify conductance defects in said precursor.

32. A method according to claim 30, wherein said filters are selected to block substantially all of said excitation light.

33. A system when used to implement the method according to claim 1.

34. A system when used to implement the method according to claim 9.

35. A system when used to implement the method according to claim 16.

36. A system when used to implement the method according to claim 18.

37. A system when used to implement the method according to claim 25.

38. A system when used to implement the method according to claim 30.

39. A non-transitory computer readable medium with an executable program stored thereon, wherein the executable program causes a system to implement the method according to claim 1.

40. A non-transitory computer readable medium with an executable program stored thereon, wherein the executable program causes a system to implement the method according to claim 9.

41. A non-transitory computer readable medium with an executable program stored thereon, wherein the executable program causes a system to implement the method according to claim 16.

42. A non-transitory computer readable medium with an executable program stored thereon, wherein the executable program causes a system to implement the method according to claim 18.

43. A non-transitory computer readable medium with an executable program stored thereon, wherein the executable program causes a system to implement the method according to claim 25.

44. A non-transitory computer readable medium with an executable program stored thereon, wherein the executable program causes a system to implement the method according to claim 30.

45. A method according to claim 18, wherein said value for ΔVₜ is calculated by the method according to claim 9.

46. A method according to claim 23, wherein local values for the series resistance of said photovoltaic cell, R_{s,i} are calculated using the equation:
$${R}_{s , i} = \frac{Δ {V}_{Rs , i}}{{J}_{Rs , i}}$$
wherein ΔV_{Rs,i} is calculated using the equation:
ΔV_{Rs,i}=ΔVₜ−ΔV_{d,i}
wherein ΔV_{d,i} values are obtained from said qualitative series resistance image.
